(19) United States
(12) Patent Application Publication
(10) Pub. No.: US 2010/0127344 A1
(43) Pub. Date: May 27, 2010

(54) CONTACT OVER ISOLATOR

(75) Inventors: Kendall S. WILLS, Sugar Land, TX (US); Reena A. CHANPURA, Sugar Land, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/275,540

(22) Filed: Nov. 21, 2008

(51) Int. Cl. H01L 29/00; H01L 21/44

(52) U.S. Cl. 257/508; 438/637; 257/E29.001; 257/E21.476

(57) ABSTRACT

An apparatus and method for providing a reliable connection to an internal node from the backside of an integrated circuit using focused ion beam (“FIB”) milling are disclosed herein. In accordance with at least some embodiments, an integrated circuit includes an isolation region, an active region, a first contact, and a metal layer. The isolation region separates adjacent integrated circuit devices. The first contact is disposed between the isolation region and the metal layer. The first contact is electrically connected to the active region. A dummy structure is disposed between the isolation region and the first contact. A FIB via is milled through the isolation region and the dummy structure to the first contact to establish an electrical connection with active region through the via.

### BACKGROUND

Integrated circuits, comprised of numerous circuit elements, are typically fabricated in layers on the surface of a semiconductor wafer. Many fabrication processes are repeated numerous times, constructing layer after layer until fabrication is complete. Metal layers (which typically increase in number as device complexity increases) include patterns of conductive material that are insulated from one another vertically by alternating layers of insulating material. Vertical, conductive tunnels called “vias” typically pass through insulating layers to form conductive pathways between adjacent conductive patterns.

Periodically, an electrical malfunction or design flaw is found when an integrated circuit is electrically tested. Implementing a design change can be an expensive process. Typically, among other tasks, a circuit designer may have to produce new schematics, a vendor may need to supply new masks or other fabrication supplies, and wafer fab personnel may need to implement new process flows on various equipment sets. Rather than commencing a lengthy and costly redesign process only to have the new design fail in operation, it is often preferable to modify and test a physical sample of the integrated circuit prior to formalizing the modified design.

Integrated circuit failure analysis often involves the use of several different types of equipment, or tools. One of the most versatile failure analysis tools is the focused ion beam (“FIB”) apparatus, which can facilitate device modification. The FIB is a tool including one or more ion columns for generating ion beams. In general, the FIB is used for performing integrated circuit repair, editing, cross-sectioning, modifications to aid microprobing of the integrated circuit, and other common failure analysis applications. As an aside, it is noted that a device may need to be preprocessed before being operated on by the FIB tool. For example, a packaged device may need to be decapsulated, or “decapped,” and an etching or grinding process for removing the encapsulant surrounding the die may need to be performed prior to operations by the FIB tool.

A FIB system generates an ion beam from a liquid metal ion source-typically gallium. Positively charged gallium ions (“Ga⁺”) are drawn off a field-emitter point source and accelerated by the application of a large potential, generally in the 30-50 kilovolt (kV) range, though in some systems the potential can be as low as 5 kV. With the aid of electrostatic lenses, the emission is focused into a beam typically having a sub-micron diameter. The ion beam can be used to mill through a sample integrated circuit, as may be required in failure analysis. The sample is usually positioned inside a vacuum chamber.

Typically, secondary electrons, secondary ions (i⁺ or i⁻), and neutral molecules and atoms are ejected from the sample surface when the ion beam impacts the sample. The charged particles are drawn toward an electrically-biased grid and collected by a detector generally positioned at an angle from the ion beam. The signal from the ejected particles may be amplified and displayed to provide a real-time image of the area of interest.

While the ion beam itself typically has a sputtering effect on the sample materials, there is often a need to add gases to assist in chemically removing material, thereby enhancing material removal process. Gas-assisted etching is a common feature in modern FIBs. An optional gas injection column delivers a localized gas to the area to be milled. This gas can interact with the primary ion beam to provide selective gas-assisted chemical etching. Alternatively, the primary ion beam can be used to decompose the gas to provide selective deposition of conductive or insulating materials on the sample.

Semiconductor device modification can be facilitated by the FIB by directing the ion beam at a localized area of the modification to be performed. The ion beam removes material in the local area, milling through the various layers. When the layer of interest is reached, circuit edits can be performed by depositing a new metal line or other material in a desired location to establish a connection, or by cutting through an existing conductive line to sever a connection.

Unfortunately, integrated circuit editing by application of a FIB, is not without its difficulties. A typical integrated circuit consists of alternating layers of conducting material and insulating dielectrics, with many layers containing patterned areas of both. Creating a reliable FIB connection to a particular integrated circuit internal node on a selected layer can be problematic. For example, imprecise endpoint detection, which can create either opens or shorts in the circuits, is one of several problems that can result in FIB edit failure. Accordingly, a reliable method of using a FIB to provide a connection to an integrated circuit internal node is desirable

### SUMMARY

Various apparatus and methods for providing a reliable connection to an internal node from the backside of an integrated circuit using a focused ion beam (“FIB”) are disclosed herein. In accordance with at least some embodiments, an integrated circuit includes an isolation region, an active region, a first contact, and a metal layer. The isolation region separates adjacent integrated circuit devices. The first contact is disposed between the isolation region and the metal layer. The first contact is electrically connected to the active region.

In accordance with at least some other embodiments, a method includes milling a via from an outer surface of an integrated circuit to a contact disposed above an isolation region of the integrated circuit. The contact is electrically connected to an active region of the integrated circuit. The via conducts a signal provided by the active region.

In accordance with yet other embodiments, a semiconductor device includes a first contact disposed over a dummy structure. The dummy structure is disposed over a shallow trench isolation (“STI”) region.

### BRIEF DESCRIPTION OF THE DRAWINGS

For a detailed description of exemplary embodiments of the invention, reference will now be made to the accompanying drawings in which:

FIG. 1 shows a side view of an exemplary integrated circuit including a contact over a dummy poly on a shallow trench isolator (“STI”) in accordance with various embodiments;

FIG. 2 shows a top view of an exemplary integrated circuit including a contact over a dummy poly on a shallow trench isolator (“STI”) in accordance with various embodiments;

FIG. 3 shows a cross-section of an exemplary integrated circuit and assorted focused ion beam via connection problems mitigated by various embodiments; and

FIG. 4 shows a flow diagram for a method for probing an internal node of an integrated circuit using a FIB in accordance with various embodiments.

### Notation and Nomenclature

Certain terms are used throughout the following description and claims to refer to particular system components. As one skilled in the art will appreciate, companies may refer to a component by different names. This document does not intend to distinguish between components that differ in name but not in function. In the following discussion and in the claims, the terms “including” and “comprising” are used in an open-ended fashion, and thus should be interpreted to mean “including, but not limited to . . . . ” The term “integrated circuit” refers to a set of electronic components and their interconnections (internal electrical circuit elements, collectively) that are patterned on the surface of a microchip. The term “semiconductor device” refers generically to an integrated circuit (“IC”) or portion thereof, which may be integral to a semiconductor wafer, singulated from a wafer, or packaged for use on a circuit board. Also, the term “couple” or “couples” is intended to mean either an indirect or direct electrical connection. Thus, if a first device couples to a second device, that connection may be through a direct electrical connection, or through an indirect electrical connection via other devices and connections. The phrase “directly coupled” is intended to mean a direct physical and/or electrical connection with no electrical devices connected interstitially between the two coupled devices. To the extent that any term is not specially defined in this specification, the intent is that the term is to be given its plain and ordinary meaning.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

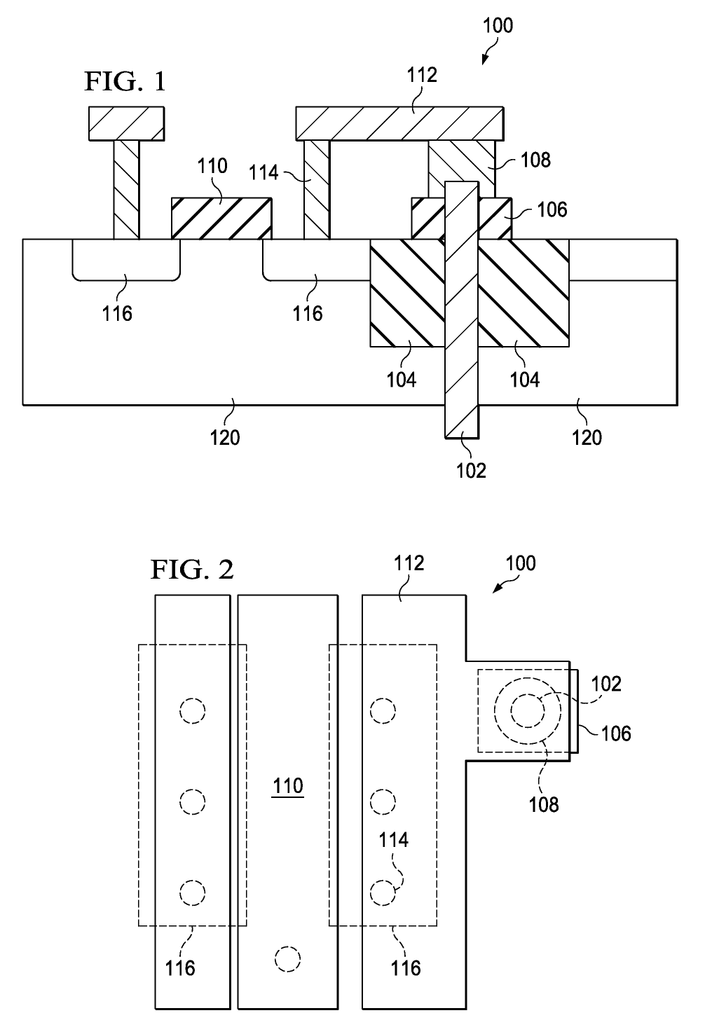

Disclosed herein are apparatus and methods for creating a reliable connection to an internal node of an integrated circuit using, for example, a focused ion beam (“FIB”). FIG. 1 shows a cross-sectional view of an integrated circuit sample 100 that includes a FIB milled via 102 in accordance with various embodiments. The exemplary embodiment 100 includes a shallow trench isolator (“STI”) 104, a dummy structure 106 disposed over the STI 104, and a contact 108 disposed on the dummy structure 106. The STI 104 preferably comprises a trench formed in substrate 120 (e.g., a silicon base layer). Shallow trenches may generally be less than 1 um in depth, but embodiments of the present disclosure are not limited to any particular trench depth. The STI 104 containing a dielectric material, for example silicon dioxide, is disposed between adjacent semiconductor components to prevent inter-component leakage.

Gate structure 110 can be, for example, the gate of a metal oxide semiconductor field effect transistor (“MOSFET”). The dummy structure 106 is generally formed of the same material as gate structure 110. In some embodiments, structures 106/110 can comprise polysilicon or metal, but are not limited to any particular material. For purposes of the present disclosure, dummy structure 110 can be referred to as a “dummy poly,” and gate structure 100 can be referred to as a “poly.” Generally, in integrated circuits, a dummy poly structure provides no function related to the device and is not connected to a voltage or current source. In embodiments of the present disclosure, however, the dummy poly 106 is disposed between the STI 104 and the contact 108. Generally, there is ample space around the active region 116 to add the contact 108 between a metal layer 112 and the STI 104 without increasing the size of the integrated circuit 100. The active region 116, can comprise, for example, the source or drain of a MOSFET, though embodiments do not limit the active region to any particular structure or device. In embodiments of the present disclosure, any voltage or current source present on the integrated circuit 100 can serve as the active region 116.

The contact 108 electrically connects the dummy poly 106 to the metal layer 112. In general, a contact provides a vertical conductive path that connects a device (e.g., the source, drain, or gate of MOSFET) to a conductive network (e.g., a metal layer). A contact, for example the contact 108, may be composed of tungsten, or any other suitable material, for example, copper, aluminum, titanium, or an alloy. The metal layer 112 interconnects various active and passive devices of the integrated circuit 100. The metal layer 112 may be formed of any suitable metal, for example, copper or aluminum.

As shown in FIG. 1, the metal layer 112, connects the contact 108 to the active region 116 of a semiconductor device through contact 114. The contact 114 is similar in construction to the contact 108 described above.

As a matter of convenience the STI 104 underlying dummy poly 106 and contact 108 is shown adjacent to active region 116, however, embodiments of the present disclosure do not require such an arrangement. Dummy poly 106 and contact 108 can be formed on any isolation structure connectable to contact 114 by metal layer 112 or any combination of metal layers and inter-layer vias.

The structure comprising the contact 108 and dummy poly 106 over the STI 104 allows the FIB milled via 102 to make a reliable connection with the active region 116 from the backside of the integrated circuit 100. As used herein, the “backside” of the integrated circuit 100 refers to the side of the die wherein no semiconductor devices are constructed. The contact 108 and dummy poly 106 over the STI 104 allow a hole to be milled from the backside of the integrated circuit 100 through the substrate 120, the STI 104, and the dummy poly 106 into the contact 108. The hole milled by the FIB is filled with a conductor (e.g., tungsten) to form the via 102. The via 102 is thus electrically connected to the active region 116 through contacts 108 and 114, and metal interconnect 112.

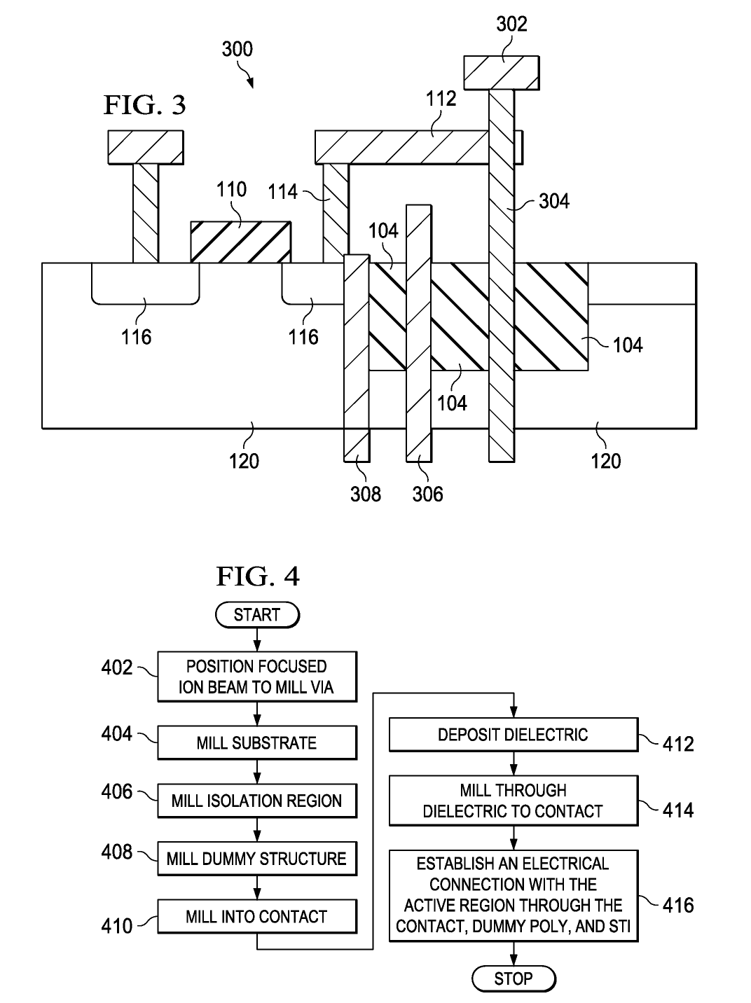

By connecting the via 102 to the contact 108 over the dummy poly 106, embodiments of the present disclosure avoid the difficulties inherent in attempting to connect the via 102 directly to the metal layer 112. FIG. 3 shows a cross-section of an exemplary integrated circuit 300 and assorted focused ion beam via connection problems mitigated by embodiments of the present disclosure. As the thickness of each metal layer decreases, and the thickness of the insulation layers disposed between metal layers decreases, the endpoint accuracy required to reliably connect to a metal layer with a FIB via without creating a short circuit to another metal layer increases. The contact 108 provides substantially more metal for the via 102 to connect with than does the metal layer 112, and reduces the likelihood of component damage that can occur when attempting to connect a via to contact 114 through the active region 116.

In FIG. 3, a via 306 illustrates an attempt to connect to the first metal layer 112. Metal layer 112 can be very thin, requiring extremely accurate determination of the via endpoint. Via 306 stops short of the metal layer 112, resulting in an open circuit.

Via 304, of FIG. 3, illustrates a second attempt to connect directly to the first metal layer 112. The insulation between metal layer 1 112 and metal layer 2 302 can be very thin. Via 304 overshoots metal layer 1 112 and comes into contact with metal layer 2 302, shorting the two metal layers.

Via 308, of FIG. 3, illustrates an attempt to mill a connection to the contact 114 connecting the active region 116 to the metal layer 112. The electrical characteristics of the active region 116 can be detrimentally changed by removal of material during milling. Moreover, milling into the contact 114 can break the connection between the contact 114 and the active region 116.

Embodiments of the present disclosure avoid these difficulties by providing a structure allowing reliable FIB connections from the integrated circuit 100 backside. Furthermore, by allowing reliable connections to the first metal layer 112 from the backside of the integrated circuit 100, embodiments avoid having to route vias across any number of intervening metal layers, as may occur when milling from the top of the die.

The metal of the contact 108 provides margin against over milling not found in other integrated circuits. Thus, the via 102 need not be milled as precisely as required in an embodiment requiring connection of the via 102 to the metal layer 112. Slight over milling of the via 102 into the contact 108 neither causes shorts to adjacent metal layers, nor disrupts contact integrity.

Each of the structures described above, including the STI 104, the dummy poly 106, the contact 108, the metal layer 112, etc. can be created using conventional integrated circuit fabrication methods and materials.

FIG. 2 shows a top view of the exemplary integrated circuit 100 including a contact 108 over a dummy poly 106 on an STI 104 in accordance with various embodiments. The active region 116 of a semiconductor device is connected to the metal layer 112 by the contact 114. The metal layer 112 also connects to the contact 108 mounted on the dummy poly 106 over the STI 104 adjacent to the active region 116. If a circuit edit or circuit probe is required, a hole can be milled from the backside of the integrated circuit 100, through the substrate 120, the STI 104, and the dummy poly 106 to the contact 108. The hole is filled with a conductor to form a reliable connection to the active region 116 through the via 102.

FIG. 4 shows a flow diagram for a method for probing an internal node of an integrated circuit using a FIB in accordance with various embodiments. Though depicted sequentially as a matter of convenience, at least some of the actions shown can be performed in a different order and/or performed in parallel. Additionally, some embodiments may perform only some of the actions shown. In block 402, connection to an internal node of the integrated circuit 100 is required. The connection may be required to probe the node, to modify a circuit, or for any other reason. The FIB is positioned at the appropriate location to mill a hole from the backside of the integrated circuit. The ion beam mills through the substrate 120 in block 404. The ion beam mills through the isolation region 104 in block 406. The isolation region 104 can be formed as an STI. Sputtering continues, in block 408, as the FIB mills through the dummy structure 106 (e.g., a dummy poly). The hole created by the FIB reaches the contact 108 in block 410.

In at least some embodiments, in block 412, a dielectric is deposited in the hole milled by the FIB. The dielectric insulates the structures through which the hole was drilled from the conductor to be deposited. In such embodiments, a second hole is milled, in block 414, through the insulator to the contact. In block 416, the hole to the contact is filled with a conductor to form a via between the contact and the backside of the integrated circuit 100. Thus, a reliable connection is formed between the active region 116 and the backside of the integrated circuit.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An integrated circuit, comprising:
an isolation region that separates adjacent integrated circuit devices; and
a first contact disposed between the isolation region and a metal layer;
wherein the first contact is electrically connected to an active region of the integrated circuit.

2. The integrated circuit of claim 1, wherein the isolation region is a shallow trench isolation region.

3. The integrated circuit of claim 1, wherein the first contact is directly coupled to the metal layer, and the metal layer electrically connects the first contact to the active region.

4. The integrated circuit of claim 1, further comprising a second contact directly coupled to the active region, the second contact connects the active region to the first contact through the metal layer.

5. The integrated circuit of claim 1, further comprising a dummy structure disposed between the isolation region and the first contact.

6. The integrated circuit of claim 5, wherein the dummy structure is a dummy poly disposed between a contact and a shallow trench isolation region.

7. The integrated circuit of claim 5, wherein the dummy structure and the first contact provide an electrical connection between the active region and a via milled through the isolation region.

8. The integrated circuit of claim 7, wherein the via is a focused ion beam milled via.

9. A method, comprising:
milling a via from an outer surface of an integrated circuit to a contact disposed above an isolation region of the integrated circuit and electrically connected to an active region of the integrated circuit;
conducting a signal provided by the active region through the via.

10. The method of claim 9, further comprising milling the via through a dummy structure connected to the contact.

11. The method of claim 9, further comprising milling the via through the isolation region.

12. The method of claim 9, further comprising forming an electrical connection to the active region through the contact, the contact disposed over a dummy poly located on a shallow trench isolator.

13. The method of claim 9, further comprising maintaining contact integrity if the via is over-milled.

14. The method of claim 9, further comprising maintaining isolation between a metal layer connected to the contact and an adjacent metal layer if the via is over-milled.

15. A semiconductor device, comprising:
a first contact disposed over a dummy structure, the dummy structure disposed over a shallow trench isolation (“STI”) region.

16. The semiconductor device of claim 15, further comprising an electrical connection between the first contact and an active region of the device.

17. The semiconductor device of claim 16, wherein the electrical connection comprises a metal layer connecting the first contact to the active region.

18. The semiconductor device of claim 15, further comprising a second contact disposed between the active region and the metal layer, the second contact electrically connecting the active region to the first contact.

19. The semiconductor device of claim 15, wherein the first contact, dummy structure, STI stack provides a connection to a focused ion beam milled via.
